(19) United States
(12) Patent Application Publication
(10) Pub. No.: US 2005/0275342 A1
(43) Pub. Date: Dec. 15, 2005

(54) Organic EL display and method of manufacturing the same

(75) Inventor: Katsuhiko Yanagawa, Nagano (JP)

Correspondence Address: ROSSI, KIMMS & McDOWELL LLP., P.O. BOX 826, ASHBURN, VA, 20146-0826, US

(73) Assignee: Fuji Electric Holdings Co., Ltd., Kawasaki-ku (JP)

(21) Appl. No.: 11/096,732

(22) Filed: Apr. 1, 2005

Related U.S. Application Data
(63) Continuation of application No. PCT/JP03/07654, filed on Jun. 13, 2003.

(51) Int. Cl. H05B 33/08; H05B 33/14; H05B 33/10

(52) U.S. Cl. 313/504; 313/503; 445/24; 445/25

(57) ABSTRACT

An organic EL display is displayed. The display is manufactured sealing and joining an organic light emitter constituted from thin film transistors, anodes, a light-emitting layer, a cathode and a protective layer which are laminated on a substrate, together with a laminated body of color filters and a black mask formed on a transparent substrate. The organic EL light-emitting layer is aligned with the color filters during the process of sealing the substrate and the transparent substrate using an outer periphery sealing layer and an internal sealing layer. The outer periphery sealing layer provides precise alignment between the organic EL light-emitting layer and the color filters and rapid fixing between them can be carried out, and prevents infiltration of moisture from the outside environment. The internal sealing layer prevents reflection of light from the organic EL light-emitting layer, and hence the light can be transmitted to the color filters effectively. The device and method prevent peeling apart due to cure shrinkage, peeling apart due to thermal stress from the temperature of the environment, and infiltration of moisture from the outside environment, so that stable light emission characteristics can be maintained over a long period.

### CROSS REFERENCE TO RELATED APPLICATIONS

This is a continuation of International Application PCT/JP2003/07564, having an international filing date of Jun. 13, 2003; this International Application was not published in English, but in Japanese, as WO2004112436.

### BACKGROUND OF THE INVENTION

A. Field of the Invention

The present invention relates to an organic EL (electroluminescent) display that is excellent in terms of high detail, environmental resistance and productivity, and can be used in a wide range of applications such as a display of mobile terminal equipment, industrial measuring equipment or the like. More particularly it relates to a so-called top emission type organic EL display and a method of manufacturing the same.

B. Description of the Related Art

In recent years, there have been rapid advances in increasing the speed of, and expanding the range of application of, information communication. Amid this, there have been many inventions with regard to high-detail display devices having low power consumption and fast response that are able to answer to the requirements on display devices with regard to portability and moving picture display.

Out of these, color display devices with a driving method that uses thin film transistors (hereinafter also referred to as ‘TFTs’) has been conceived for methods of achieving color. In this case, with a constitution in which the light is extracted from the side of the substrate on which the TFTs are formed, due to the effect of wiring parts blocking the light, the aperture ratio cannot be raised. Recently display devices in which the light is extracted from the opposite side to the substrate on which the TFTs are formed, i.e., display devices of a so-called top emission type, have been developed.

In the case of a top emission type device in which light emitters of the three primary colors red, green and blue are arranged separated from one another in a matrix, light-emitting materials for red, green and blue must be arranged with high detail in the matrix, and hence it is difficult to carry out their manufacture efficiently and cheaply. Moreover, drawbacks remain such as it being difficult to maintain good color reproduction over a long period due to the brightness change characteristics and driving conditions being different for the three types of light-emitting material. In addition, when color filters are used with a backlight that emits white light, thus transmitting the three primary colors separated from one another, the problem of making the backlight have high efficiency remains.

A high-detail high-brightness organic EL display can be provided by adopting the top emission type using the TFT driving method with a color conversion type in which fluorescent bodies that are arranged separated from one another are made to absorb light and hence fluorescence of a plurality of colors is emitted from the fluorescent bodies. This is disclosed in Japanese Patent Application Laid-open No. 11-251059 and Japanese Patent Application Laid-open No. 2000-77191.

A schematic sectional view of an example of a conventional top emission type organic EL display is shown in FIG. 2. TFTs 2, anodes 3, organic EL light-emitting layer 4, and cathode 5 are formed on substrate 1. Color filters 12 and black mask 13 are then formed on transparent substrate 11. Next, sealing layer 31 is formed at a periphery of substrate 1 using, for example, a room temperature curable two-liquid epoxy adhesive, and substrate 1 is bonded to transparent substrate 11. At this time, internal space 32 is formed between the two substrates. Rather a long time of 24 hours is required to cure sealing layer 31 at room temperature, and after organic EL light-emitting layer 4 and color filters 12 have been aligned with one another, the substrates must be fixed during the curing at room temperature so that they do not slip out of position. With the display shown in FIG. 2, it is necessary for the display to have a detailed color display capability, for the EL device to have long-term stability with regard to color reproducibility and so on, and for manufacture in a short time to be possible.

With an organic EL display as shown in FIG. 2, precise alignment between organic EL light-emitting layer 4 and color filters 12 is necessary, and it must be possible to adjust the alignment freely without the adhesive used in sealing layer 31 undergoing a change in properties such as a change in viscosity or gelation until the alignment has been completed. On the other hand, the curing must be completed rapidly after the alignment has been completed, i.e., conflicting curing properties are required.

Moreover, there is a problem of light emitted from organic EL light-emitting layer 4 being reflected at an air layer interface where the refractive index changes greatly due to the influence of internal space 32 formed between the two substrates. To resolve this problem, one can envisage filling a material having a high refractive index into internal space 32 and then curing this material. However, if the elastic modulus of the filled material is high, then peeling away from the organic EL light-emitting layer or the color filter layers will occur due to thermal stress produced upon a change in the temperature of the usage environment.

In Japanese Patent Application Laid-open No. 3-190084, there is description of the two substrates being bonded together at a bonding portion using an epoxy resin, and then filling an insulating material into the internal space. However, with the invention described in Japanese Patent Application Laid-open No. 3-190084, the problems peculiar to a top emission type organic EL display are not resolved. First, there is the point that due to the necessity of carrying out precise alignment between the organic EL light-emitting layer and the color filters, the adhesive must not start curing during the alignment, and moreover there is also the point that after the alignment has been completed, the adhesive is required to cure in a short time for the outer periphery sealing layer. Second, there is the point that a material that has a high refractive index so that light from the organic EL light-emitting layer is not reflected but rather is transmitted effectively to the color filters and has a function of alleviating peeling apart due to thermal stress is required for the internal sealing layer.

The present invention is directed to overcoming or at least reducing the effects of one or more of the problems set forth above.

### SUMMARY OF THE INVENTION

It is therefore an object of the present invention to provide an outer periphery sealing constitution according to which precise alignment between the organic EL light-emitting layer and the color filters can be carried out, and curing can be carried out in a short time, and an organic EL display according to which light from the organic EL light-emitting layer can be transmitted to the color filters effectively without being reflected, infiltration of moisture and so on from the outside environment can be prevented, and stable light emission characteristics can be maintained over a long period, and a method of manufacturing such an organic EL display.

To attain the above object, there is provided according to the present invention An organic EL display comprising (A) an organic EL light emitter that is driven by thin film transistor and comprises (i) thin film transistors formed on a substrate, each thin film transistor having a source and a drain, and (ii) a laminate formed on the thin film transistors that comprises first electrodes that are made of an electrically conductive thin film material, each of the first electrodes being connected to a source or a drain, an organic EL light-emitting layer, a second electrode that is made of at least a transparent electrically conductive material, and a protective layer; and (B) a laminated body comprising a transparent substrate and color-converting filter layers formed on the transparent substrate. The organic EL light emitter and the laminated body are sealed and joined together with the organic EL light-emitting layer being aligned with the color-converting filter layers, by sealing and joining the substrate of the organic EL light emitter and the transparent substrate of the laminated body with an outer periphery sealing layer. There is an internal sealing layer that is filled inside the outer periphery sealing layer for suppressing reflection at internal space interfaces of light emitted from the organic EL light-emitting layer.

A UV-curable adhesive or a visible light-curable adhesive is preferably used in the outer periphery sealing layer, and an elastic transparent sealant having a refractive index of 1.3 to 2.5 is preferably used in the internal sealing layer. A transparent silicone rubber material or a transparent silicone gel material may be used as the elastic transparent sealant.

Also provided according to the invention is a manufacturing method. The method comprises forming an organic EL light emitter, which is constituted by thin film transistors that are formed on a substrate and each have a source and a drain, and a laminate formed on the thin film transistors and composed of first electrodes that are made of an electrically conductive thin film material and are each connected to the source or the drain, an organic EL light-emitting layer, a second electrode that is made of at least a transparent electrically conductive material, and a protective layer, the organic EL light emitter being driven by the thin film transistors; forming a laminated body having a transparent substrate, and color-converting filter layers formed on the transparent substrate; precisely aligning and bonding less than the entire outer periphery of the substrate and the transparent substrate together using a sealant to form a space bounded by the substrate, the transparent substrate and the sealant; filling the space with a sealant to form an internal sealing layer; and applying more sealant to close that portion of the outer periphery sealing layer that was left open when the outer periphery of the substrate and the transparent substrate were aligned and bonded.

The outer periphery sealing layer must function to enable precise alignment between the organic EL light-emitting layer and color filters in the color-converting filter layers, and cure in a short time. It also must function to prevent infiltration of moisture and so on from the outside environment after curing. Thus, a material as described above is suitable.

The internal sealing layer must have a high refractive index so as to transmit light from the organic EL light-emitting layer to the color filters, and must function to prevent peeling apart due to cure shrinkage upon curing, and to alleviate peeling apart due to thermal stress from the temperature of the environment. A material as above having a refractive index of 1.3 to 2.5 and a compression modulus of not more than 0.5 kg/mm² (490 MPa) is thus suitable. Regarding the refractive index, the refractive indices of other constituent elements (e.g., the cathode) of the organic light emitter will be in a range of 1.3 to 2.5, and hence filling in a material having a refractive index in this range, i.e., reducing changes in refractive index, leads to a reduction in the loss of light. Moreover, the above range for the compression modulus has been determined from experience.

### BRIEF DESCRIPTION OF THE DRAWINGS

The foregoing advantages and features of the invention will become apparent upon reference to the following detailed description and the accompanying drawings, of which:

FIG. 1 is a sectional view showing the structure of an organic EL display of the present invention.

FIG. 2 is a sectional view showing the structure of a conventional organic EL display.

### DETAILED DESCRIPTION OF SPECIFIC EMBODIMENTS

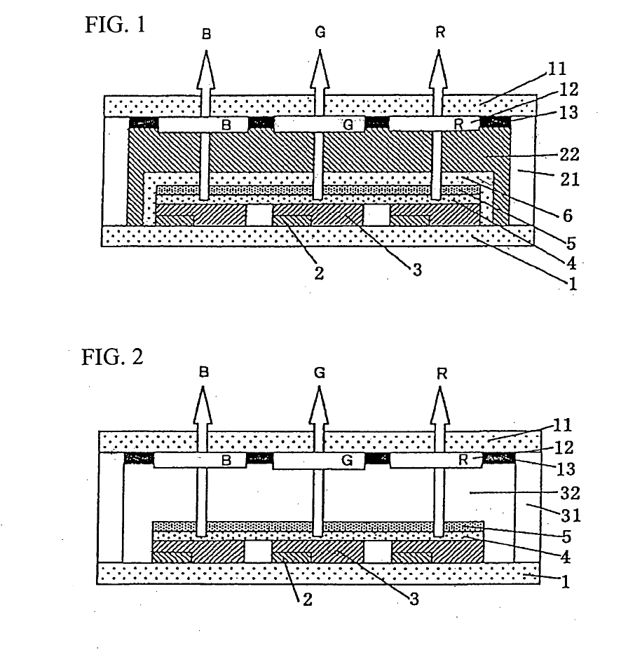

Following is a description of an organic EL display of the present invention. FIG. 1 is a sectional view of the constitution of an organic EL display, showing an embodiment of the present invention. In the following, the case that the first electrodes are anodes 3 is described, but the first electrodes may be made to be cathodes.

A. Organic EL Light Emitter

An organic EL light emitter in the present invention comprises substrate 1, TFTs 2 formed on substrate 1, a flattening insulating film (not shown), anodes 3, organic EL light-emitting layer 4, cathode 5, and protective layer 6.

1: TFT Section

The TFT section of the organic EL display of the present invention comprises substrate 1, TFTs 2, the flattening insulating film, and anodes 3.

TFTs 2 are arranged in a matrix on substrate 1, which is an insulating substrate made of glass, plastic or the like, or a semiconductive or conductive substrate having an insulating thin film formed thereon, and source electrodes are connected to anodes 3 in correspondence with the pixels.

The flattened insulating film is formed on TFTs 2. This insulating film is provided except at portions required for connection between the source electrodes and anodes 3 or connection to other circuitry, and flattens the surface of substrate 1, thus making high-detail patterning of subsequent layers easy. The source electrodes and anodes 3 may also be connected together by electrically conductive plugs filled into contact holes provided in the flattening insulating film.

Anodes 3 are formed on the flattening insulating film formed on TFTs 2. A material having a high work function is used for anodes 3 so that injection of holes can be carried out efficiently. In the case of the top emission method of the present invention, anodes 3 are not required to be transparent, but an electrically conductive metal oxide such as ITO or IZO can nevertheless be used. Furthermore, in the case of using an electrically conductive metal oxide, it is preferable to use an electrode of a metal having high reflectivity (aluminum, silver, molybdenum, tungsten etc.) therebelow. Such a metal electrode has lower resistivity than the electrically conductive metal oxide and thus functions as an auxiliary electrode, and moreover reflects light emitted by the organic EL light-emitting layer 4 toward color filter 12 side, enabling the light to be utilized effectively.

In the case of using the first electrodes as cathodes, the first electrodes are connected to the drains of TFTs 2. Moreover, instead of the electrically conductive metal oxide, a material having a low work function, i.e., an electron-injecting metal selected from alkali metals such as potassium, lithium and sodium, alkaline earth metals such as calcium, magnesium and strontium, and fluorides and so on thereof, or an alloy thereof with other metals or a compound thereof is used.

2: Organic EL Light-Emitting Layer and Cathode

Organic EL light-emitting layer 4 and cathode 5 are provided on TFT 2 section on which TFTs 2 and anodes 3 have been patterned. In the case of using the color conversion method, light in the near ultraviolet region to visible region, preferably light in the blue to blue/green region, emitted from organic EL light-emitting layer 4 is introduced into color-converting filter layers, and visible light of a desired color is emitted.

For organic EL light-emitting layer 4, giving the structure including anodes 3 and cathode 5, if necessary a hole injection layer, a hole transport layer and/or an electron injection layer are interposed, and hence specifically a layer structure such as the following is adopted:
anodes, organic EL light-emitting layer, cathode
anodes, hole injection layer, organic EL light-emitting layer, cathode
anodes, organic EL light-emitting layer, electron injection layer, cathode
anodes, hole injection layer, organic EL light-emitting layer, electron injection layer, cathode
anodes, hole injection layer, hole transport layer, organic EL light-emitting layer, electron injection layer, cathode.

Publicly-known materials are used as the materials of the above-mentioned layers. To obtain luminescence from blue to blue/green in color, for example a fluorescent whitening agent of benzothiazole type or the like, a metal chelated oxonium compound, or the like is preferably used in organic EL light-emitting layer 4.

The material used for cathode 5 is required to have a low work function for efficient injection of electrons. Furthermore, with the top emission color conversion method of the present embodiment, the light from organic EL light-emitting layer 4 is emitted via cathode 5, and hence cathode 5 must be transparent in the wavelength region of this light. To satisfy both of these properties, cathode 5 is preferably made to have a multi-layered structure in the present invention. This is because materials having a low work function generally have low transparency. Specifically, a thin film of an electron-injecting metal selected from alkali metals such as potassium, lithium and sodium, alkaline earth metals such as calcium, magnesium and strontium, and fluorides and so on thereof, or an alloy thereof with other metals or a compound thereof is used as a part contacting the organic EL light-emitting layer. By using such a material having a low work function, efficient injection of electrons is made possible, and moreover by making the film of this material be thin, the reduction in transparency due to this material can be minimized. A transparent electrically conductive film of ITO, IZO or the like is formed on this thin film. This electrically conductive film acts as an auxiliary electrode, whereby the resistance of cathode 5 as a whole can be reduced, and hence a sufficient current can be supplied to the organic EL light-emitting layer.

In the case of using the second electrode as an anode, a material having a high work function must be used to increase the efficiency of hole injection. Moreover, the light emitted from organic EL light-emitting layer 4 passes through the second electrode, and hence a material having high transparency must be used. ITO or IZO is preferable.

3: Protective Layer 6

Protective layer 6 is provided covering the various layers from the second electrode downward formed as described above. Protective layer 6 is effective in preventing oxygen, low-molecular-weight components and moisture penetrating in from the outside environment, and thus preventing a deterioration in the functioning of organic EL light-emitting layer 4. Protective layer 6 preferably has a suitable hardness for facilitating formation of other layers thereon.

To satisfy these requirements, protective layer 6 is formed from a material that has high transparency in the visible region (a transmissivity of at least 50% in a range of 400 to 700 nm), is electrically insulating, acts as a barrier against moisture, oxygen and so on, and preferably has a film hardness of at least 2H. For example, a material such as an inorganic oxide or inorganic nitride such as SiOₓ, SiNₓ, AlOₓ, TiOₓ, TaOₓ or ZnOₓ can be used. As the method of forming the protective layer, sputtering, vapor deposition, dipping, CVD or the like can be used.

Moreover, any of various polymer materials can be used for protective layer 6. For example, an imide-modified silicone resin, or a material obtained by dispersing an inorganic metal oxide such as titanium oxide in an acrylic, polyimide or silicone resin or the like can be used.

Protective layer 6 may be a single layer, but the effect is great if a plurality of layers are built up on top of one another. The thickness of protective layer 6 is preferably 0.1 to 10 μm.

B. Color-Converting Filters

The color-converting filters in the present invention are formed on transparent substrate 11, which is a second substrate, and comprise color filters 12 corresponding to various desired colors, or laminates of such color filters 12 and fluorescent color-converting layers (omitted from the drawings), and black mask 13. Note that in the following description, the transparent substrate will be included in the description.

1: Transparent Substrate

A plastic material in the form of a film is preferable as transparent substrate 11. The thickness thereof is suitably from 20 to 500 μm. If such a plastic film is used as the substrate, then the organic EL display of the present invention can be made lighter than in the case that glass is used, and can be made stronger to bending stress. However, glass is not excluded from being used as the transparent substrate in the present invention.

Note that in the present specification, ‘transparent’ means transmitting 10 to 100% of visible light. The transmissivity to visible light will also depend on the converting performance of fluorescent colorants used in any fluorescent color-converting layers, but is preferably approximately 40 to 80%.

2: Color-Converting Filter Layers

In the present specification, as described above, the color-converting filter layers comprise color filters 12, or laminates of color filters 12 and fluorescent color-converting layers (not shown), and black mask 13. A fluorescent color-converting layer is a layer that absorbs light in the near ultraviolet region or visible region, in particular light in the blue or blue/green region, emitted from the organic EL light-emitting layer, and emits visible light of a different wavelength as fluorescence. To enable full-color display, independent layers that emit light in at least the blue region, the green region and the red region are provided.

For the red color, the color-converting filter layers may be formed from only fluorescent color-converting layers. However, in the case that sufficient color purity cannot be obtained through only conversion by a fluorescent colorant, laminates of fluorescent color-converting layers and color filters may be used. This is the same for the green color.

For the blue color, on the other hand, in the case that the organic EL light-emitting layer emits blue light, the color-converting filter layers can be made to be color filters only. The thickness thereof is preferably 1 to 10 μm.

The form of the color-converting filter layers may be made to be a pattern of separated stripes for each color, or the color-converting filter layers may have a structure separated into sub-pixels for each pixel, this being as publicly known.

Black mask 13 is preferably formed in regions between the color-converting filter layers corresponding to the various colors. By providing black mask 13, leakage of light into the color-converting filters of neighboring sub-pixels can be prevented, whereby the desired fluorescent converted colors only can be obtained with no blurring. Black mask 13 preferably has a thickness of 1 to 6 μm.

C. Sealing Layers

1: Internal Sealing Layer

Internal sealing layer 22 is provided by filling a sealant into internal space 32 that is formed in the display in the case of the conventional method, this being to suppress reflection of light emitted from organic EL light-emitting layer 4 at interfaces of the internal space, so that the emitted light can be transmitted to color filters 12 efficiently. Internal sealing layer 22 is formed from a material having a visible light transmissivity of 10 to 100%, preferably at least 50%, to light of wavelength 400 to 800 nm, and a refractive index of 1.3 to 2.5. Examples of such a material are organic materials such as transparent silicone rubbers and transparent silicone gels.

The filler may be filled in between the two substrates through an injection port provided in outer periphery sealing layer 21, this being after the two substrates have been bonded together using outer periphery sealing layer 21. By using such a filler, the refractive index difference along the path along which the light emitted from organic EL light-emitting layer 4 is transmitted can be reduced, and hence reflection at interfaces can be suppressed, and thus the transmission of the light to color filters 12 can be carried out more efficiently

2: Outer Periphery Sealing Layer

Outer periphery sealing layer 21 is provided at an outer peripheral portion of the substrates, and bonds substrate 1 and transparent substrate 11 together, and moreover protects the various internal constituent elements from oxygen, moisture and so on from the outside environment. Outer periphery sealing layer 21 is formed from a visible light-curable adhesive or a UV-curable adhesive, and may also contain beads of diameter 3 to 50 μm therein. In this case, the distance between the substrates is stipulated by the beads, and moreover pressure applied for the bonding can be born by the beads. Furthermore, stress generated when driving the display will be created, whereby degradation of the display due to such stress can be prevented.

In the case that internal sealing layer 22 is formed by being injected after substrate 1 and transparent substrate 11 have been bonded together, a non-applied portion can be provided in part of outer periphery sealing layer 21, with this non-applied portion being used as the injection port for the internal sealing layer. This injection port can be closed up by applying and curing some of the outer periphery sealing layer material after the injecting in has been completed.

Following is a detailed description of examples of the present invention.

### EXAMPLE 1

TFTs 2, anodes 3, organic EL light-emitting layer 4, cathode 5, and protective layer 6 were formed in this order on substrate 1 (a glass substrate in the present example) as shown in FIG. 1. Next, color filters 12 and black mask 13 were formed in this order on transparent substrate 11 (a transparent glass substrate in the present example). The two substrates formed in this way were then subjected to the following process under a dry nitrogen atmosphere (oxygen and moisture concentration both not more than 1 ppm) in a glove box.

Outer periphery sealing layer 21 using a UV-curable adhesive (made by Three Bond, trade name: 30Y-437), which is an epoxy type material, was formed using a dispenser robot (an adhesive applying apparatus, driven by a XY robot) on an outer peripheral portion of glass substrate 1 on the organic EL light-emitting layer side, and transparent glass substrate 11 was bonded on from the color filter 12 side.

At this time, outer periphery sealing layer 21 was applied in a shape having a non-applied portion (not shown) provided in part thereof (in the present example, the non-applied portion was provided in part of the quadrangular display outer periphery), with the non-applied portion being subsequently used as a material injection port for internal sealing layer 22.

After that, alignment was carried out to match up organic EL light-emitting layer 4 and color filters 12, and then outer periphery sealing layer 21 was cured by irradiating with UV radiation for 30 seconds at an intensity of 100 mW/cm² and a wavelength of 365 nm as UV curing conditions.

Next, a transparent silicone rubber material (made by Shin-Etsu Chemical Co., Ltd., trade name: KE103) having a refractive index of approximately 1.45 and a compression modulus of not more than 0.5 kg/mm² was injected using a dispenser through the injection port provided in part of outer periphery sealing layer 21, and then curing was carried out for 60 minutes at 80° C., thus forming internal sealing layer 22. After that, the material injection port provided in outer periphery sealing layer 21 was sealed using the same UV-curable adhesive as in outer periphery sealing layer 21, thus completing the organic EL display.

Note that in the present example, blue light was emitted from the organic EL light-emitting layer. Consequently, blue color filters 12 were constituted from filters only, but for each of the green and red color filters 12, laminates of filters and fluorescent layers (not shown) that carry out wavelength conversion were used. Moreover, the thickness of the internal sealing layer was 3 to 5 μm (approximately 10 μm at most), and the thickness of the outer periphery sealing layer was 5 to 30 μm (approximately 100 μm at most).

Through the above, the gap between substrate 1 and transparent substrate 11 was fixed at 5 to 10 μm, and an organic EL display having long-term reliability was obtained, with infiltration of moisture from the outside environment being prevented.

Here, according to the present invention, by forming a display as in the example described above, it is possible to carry out precise alignment between organic EL light-emitting layer 4 and color filters 12. Specifically, alignment is carried out using markers, omitted from the drawings, provided on each of substrate 1 and transparent substrate 11, and at this time the adhesive used for outer periphery sealing layer 21 is required to have the following two properties. That is, it must be made such that alignment (slight movement) can be carried out freely, without the applied adhesive curing until the two substrates have been placed together and the alignment using the markers has been completed, and moreover the applied adhesive is required to cure completely in a short time after the alignment has been completed. By using a UV-curable adhesive as described above, or a visible light-curable adhesive as described below, these two properties are satisfied.

### EXAMPLE 2

The constitution of the substrates in the present embodiment was the same as in Example 1. However, a visible light-curable adhesive was used for outer periphery sealing layer 21, and a transparent silicone gel material was used for internal sealing layer 22. The visible light-curable adhesive was, for example, Luxtrak LCR0275 (trade name) made by Toagosei Co., Ltd., this being an acrylic material. Moreover, the curing conditions were a wavelength of 400 nm, an intensity of 100 mW/cm², and an irradiation time of 30 seconds. Such a visible light-curable adhesive is advantageous in terms of the equipment cost, since the irradiation apparatus is cheaper than for a UV-curable adhesive. The transparent silicone gel material was KE104Gel (trade name) made by Shin-Etsu Chemical Co., Ltd., and had a refractive index of approximately 1.45, and a compression modulus of not more than 0.5 kg/mm².

According to the present invention, as a result of adopting the constitution described above, due to the outer periphery sealing layer, precise alignment between the organic EL light-emitting layer and the color filters and rapid fixing between them can be carried out, and moreover infiltration of moisture and so on from the outside environment can be prevented. Furthermore, due to the internal sealing layer, reflection of light from the organic EL light-emitting layer can be prevented, and hence the light can be transmitted to the color filters effectively, and moreover peeling apart due to cure shrinkage upon curing can be prevented, peeling apart due to thermal stress from the temperature of the environment can be alleviated, and infiltration of moisture and so on from the outside environment can be prevented, and hence stable light emission characteristics can be maintained over a long period.

Thus, an organic EL display and a method of manufacturing the same has been described according to the present invention. Many modifications and variations may be made to the techniques and structures described and illustrated herein without departing from the spirit and scope of the invention. Accordingly, it should be understood that the devices and methods described herein are illustrative only and are not limiting upon the scope of the invention.

1. An organic EL display comprising:
(A) an organic EL light emitter that is driven by thin film transistor and comprises
(i) thin film transistors formed on a substrate, each thin film transistor having a source and a drain, and
(ii) a laminate formed on the thin film transistors that comprises first electrodes that are made of an electrically conductive thin film material, each of the first electrodes being connected to either a source or a drain, an organic EL light-emitting layer, a second electrode that is made of at least a transparent electrically conductive material, and a protective layer; and
(B) a laminated body comprising a transparent substrate and color-converting filter layers formed on the transparent substrate,
wherein the organic EL light emitter and the laminated body are sealed and joined together with the organic EL light-emitting layer being aligned with the color-converting filter layers, by sealing and joining the substrate of the organic EL light emitter and the transparent substrate of the laminated body with an outer periphery sealing layer, and
wherein there is an internal sealing layer that is filled inside the outer periphery sealing layer for suppressing reflection at internal space interfaces of light emitted from the organic EL light-emitting layer.

2. The organic EL display according to claim 1, wherein a UV-curable adhesive or a visible light-curable adhesive is used in the outer periphery sealing layer.

3. The organic EL display according to claim 1 or 2, wherein an elastic transparent sealant having a refractive index of 1.3 to 2.5 is used in the internal sealing layer.

4. The organic EL display according to claim 3, wherein a transparent silicone rubber material or a transparent silicone gel material is used as the elastic transparent sealant.

5. A method of manufacturing an organic EL display, comprising:
forming an organic EL light emitter, which is constituted by thin film transistors that are formed on a substrate and each have a source and a drain, and a laminate formed on the thin film transistors and composed of first electrodes that are made of an electrically conductive thin film material and are each connected to either a source or a drain, an organic EL light-emitting layer, a second electrode that is made of at least a transparent electrically conductive material, and a protective layer, the organic EL light emitter being driven by the thin film transistors;
forming a laminated body having a transparent substrate, and color-converting filter layers formed on the transparent substrate;
precisely aligning and bonding less than the entire outer periphery of the substrate and the transparent substrate together using a sealant to form a space bounded by the substrate, the transparent substrate and the sealant;
filling the space with a sealant to form an internal sealing layer; and
applying more sealant to close that portion of the outer periphery sealing layer that was left open when the outer periphery of the substrate and the transparent substrate were aligned and bonded.
